(19) United States
(12) Patent Application Publication
(10) Pub. No.: US 2014/0242793 A1
(43) Pub. Date: Aug. 28, 2014

(54) PATTERN FORMING METHOD AND METHOD OF MANUFACTURING SEMICONDUCTOR DEVICE

(71) Applicant: KABUSHIKI KAISHA TOSHIBA, Minato-ku (JP)

(72) Inventor: Tomoyuki TAKEISHI, Mie (JP)

(73) Assignee: KABUSHIKI KAISHA TOSHIBA, Minato-ku (JP)

(21) Appl. No.: 13/954,307

(22) Filed: Jul. 30, 2013

Related U.S. Application Data
(60) Provisional application No. 61/770,009, filed on Feb. 27, 2013.

(51) Int. Cl. H01L 21/768

(52) U.S. Cl. CPC H01L 21/76802; H01L 21/76814
USPC 438/666

(57) ABSTRACT

According to one embodiment, a core material is ejected onto an object using an inkjet method to form a core pattern on the object, a mask pattern is formed on the object so as to embed the core pattern, and the core pattern which is embedded in the mask pattern is removed.

### CROSS-REFERENCE TO RELATED APPLICATIONS

This application is based upon and claims the benefit of priority from Provisional Patent Application No. 61/770009, filed on Feb. 27, 2013; the entire contents of which are incorporated herein by reference.

### FIELD

Embodiments of the present invention relate generally to a pattern forming method and a method of manufacturing a semiconductor device.

### BACKGROUND

For a laminated structure of semiconductor chips, a TSV (through silicon via) technique is used. In the TSV technique, in order to form a through hole in a semiconductor substrate, a photo-etching process is performed on the semiconductor substrate.

### BRIEF DESCRIPTION OF THE DRAWINGS

FIG. 1A is a perspective view illustrating an example of a schematic configuration of a semiconductor chip which is used for a method of manufacturing a semiconductor device according to a first embodiment, and

FIG. 1B is a perspective view illustrating a schematic configuration of a semiconductor wafer from which the semiconductor chip of FIG. 1A is cut out.

FIGS. 2A to 2E are cross-sectional views illustrating the method of manufacturing a semiconductor device according to the first embodiment.

FIGS. 3A to 3D are cross-sectional views illustrating the method of manufacturing a semiconductor device according to the first embodiment.

FIGS. 4A to 4C are cross-sectional views illustrating a method of manufacturing a semiconductor device according to a second embodiment.

### DETAILED DESCRIPTION

According to an embodiment, a core material is ejected onto an object using an inkjet method to form a core pattern on the object, a mask pattern is formed on the object so as to embed the core pattern, and the core pattern which is embedded in the mask pattern is removed.

Hereinafter, with reference to accompanying drawings, a pattern forming method and a method of manufacturing a semiconductor device according to an embodiment will be described in detail. However, the present invention is not limited by the embodiments.

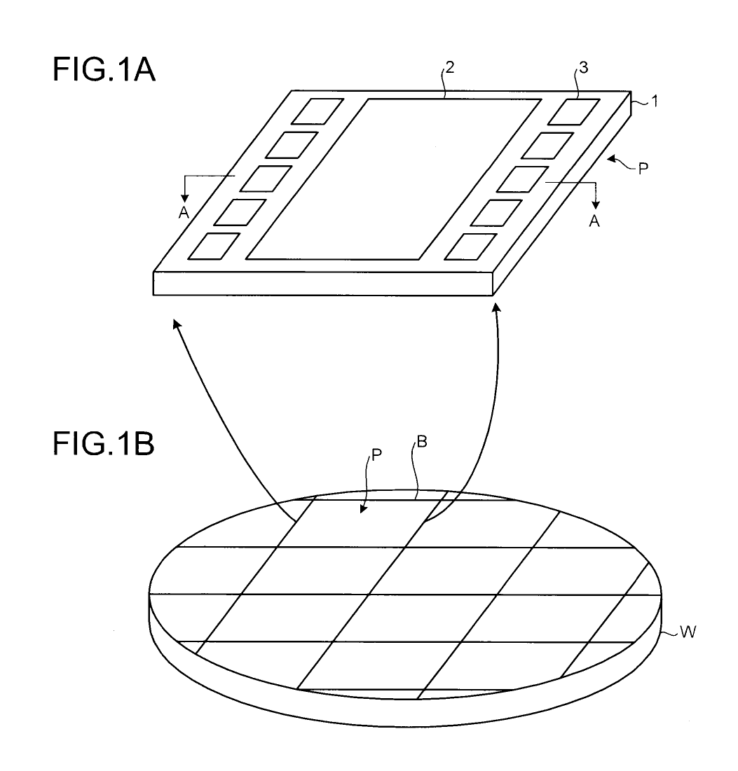

FIG. 1A is a perspective view illustrating an example of a schematic configuration of a semiconductor chip which is used for a method of manufacturing a semiconductor device according to a first embodiment, and FIG. 1B is a perspective view illustrating a schematic configuration of a semiconductor wafer from which the semiconductor chip of FIG. 1A is cut out.

Referring to FIG. 1A, an integrated circuit 2 is formed on a semiconductor chip P, and pad electrodes 3 are formed on the periphery of the semiconductor chip P. Further, the integrated circuit 2 may be a storage device such as an NAND flash memory, a DRAM, or an SRAM or a logical circuit such as an ASIC, or an arithmetic device such as a processor.

Here, as illustrated in FIG. 1B, the integrated circuit 2 and the pad electrodes 3 are formed on a semiconductor wafer W and the semiconductor wafer W is cut along a scribe line B to cut out the semiconductor chip P.

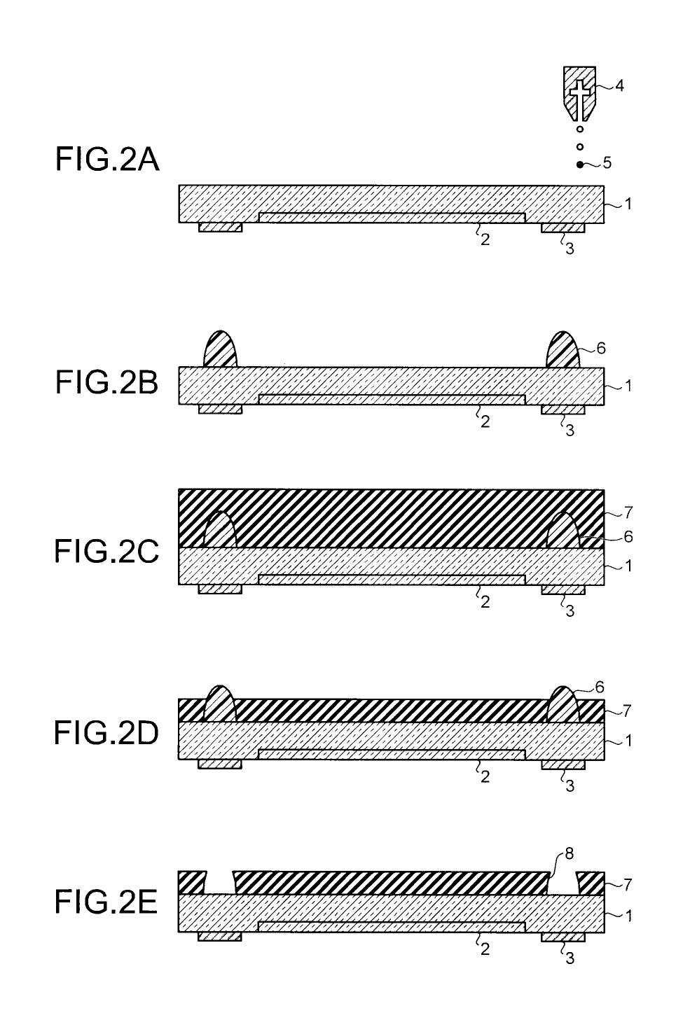

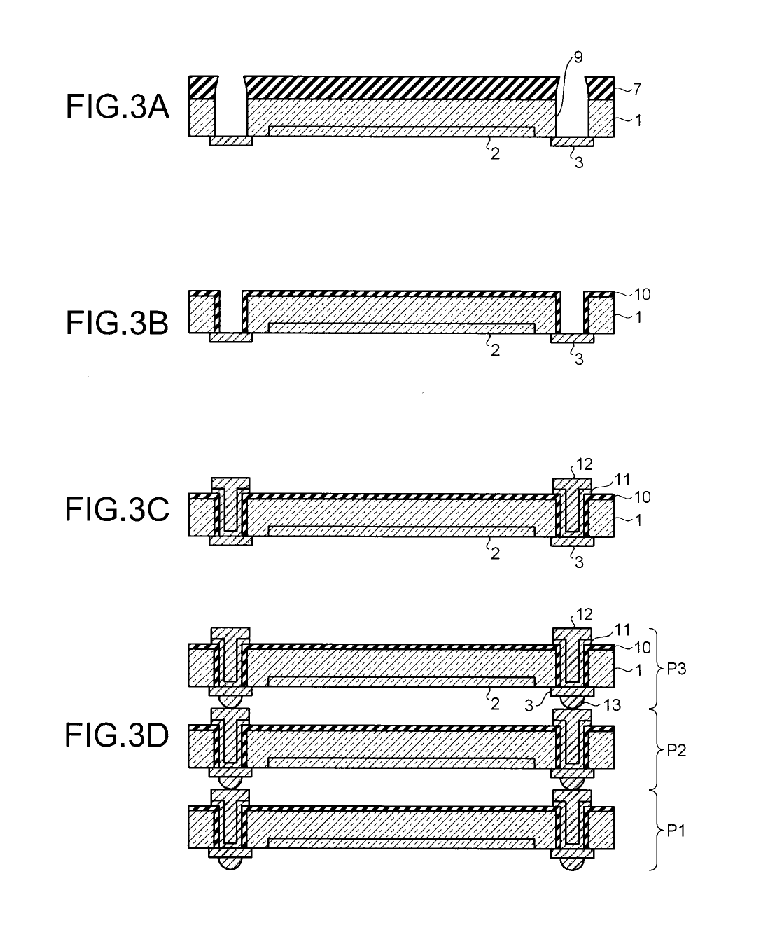

FIGS. 2A to 2E and FIGS. 3A to 3D are cross-sectional views illustrating the method of manufacturing a semiconductor device according to the first embodiment. Further, FIGS. 2A to 2E and FIGS. 3A to 3D illustrate a portion cut along A-A line of FIG. 1A.

Referring to FIG. 2A, a core material 5 is ejected on a rear surface of a semiconductor substrate 1 from a nozzle 4 using an inkjet method to form a core pattern 6 on the rear surface of the semiconductor substrate 1, as illustrated in FIG. 2B. In this case, the core pattern 6 is desirably disposed at an inner side of the pad electrode 3. As a material of the core material 5, an organic film such as a resist or polyimide may be used. A particle size of the core material may be set to be 50 nm or smaller. A thickness of the core pattern 6 is desirably 10 μm or larger.

Next, as illustrated in FIG. 2C, a mask pattern 7 is formed on the rear surface of the semiconductor substrate 1 using a method such as a coating method so as to embed the core pattern 6. Further, a material for the mask pattern 7 may be selected so as to have an etching rate which is lower than that of the core pattern 6, for example, an inorganic film such as SOG (spin on glass) may be used. In this case, the entire core pattern 6 may be embedded in the mask pattern 7 or the core pattern 6 may be embedded in the mask pattern 7 so as to expose an upper portion of the core pattern 6.

Next, as illustrated in FIG. 2D, when the entire core pattern 6 is embedded in the mask pattern 7, the mask pattern 7 is thinned using a method such as RIE or CMP so that the upper portion of the core pattern 6 is exposed.

Next, as illustrated in FIG. 2E, the core pattern 6 is removed to form an opening 8, on which the core pattern 6 is transferred, on the mask pattern 7. When the core pattern 6 is the organic film and the mask pattern 7 is SOG, an ashing process such as oxygen plasma may be performed to selectively remove the core pattern 6.

Next, as illustrated in FIG. 3A, the semiconductor substrate 1 is etched from the rear surface using the mask pattern 7 on which the opening 8 is formed as a mask to form a through hole 9 in the semiconductor substrate 1. In this case, the through hole 9 may be disposed at an inner side of the pad electrode 3. Further, the rear surface of the pad electrode 3 may be exposed through the through hole 9.

Next, as illustrated in FIG. 3B, the mask pattern 7 is removed using a method such as a wet etching process. Further, when the mask pattern 7 is SOG, hydrofluoric acid may be used as a chemical of the wet etching process. Next, an insulating film 10 is formed on the rear surface of the semiconductor substrate 1 using a CVD method so as to cover a side surface of the through hole 9. Further, for example, a silicon dioxide film may be used as the insulating film 10. Further, the insulating film 10 which is attached onto the rear surface of the pad electrode 3 may be selectively removed by an RIE method.

Next, as illustrated in FIG. 3C, an embedded electrode 12 which is connected to the rear surface of the pad electrode 3 with a seed layer 11 interposed therebetween is embedded in the through hole 9. As a method of embedding the embedded electrode 12 in the through hole 9, for example, electrolytic plating may be used. For example, TiN may be used for the seed layer 11 and Cu may be used for the embedded electrode 12.

The above described processes of FIGS. 2A to 2E and FIGS. 3A to 3C may be performed in a state of the semiconductor wafer W of FIG. 1B. Therefore, the semiconductor wafer W in which the embedded electrode 12 is embedded is cut along the scribe line B to cut out the semiconductor chip P.

Next, as illustrated in FIG. 3D, semiconductor chips P1 to P3 in which embedded electrodes 12 are embedded are laminated with protruding electrodes 13 therebetween and pad electrodes 3 and the embedded electrodes 12 of upper and lower semiconductor chips P1 to P3, respectively, are connected. Further, the protruding electrode 13 may be, for example, a solder ball or a metal bump which is formed of Au or Ni. Further, the semiconductor chips P1 to P3 are inspected before laminating the semiconductor chips P1 to P3 and only non-defective semiconductor chips P1 to P3 may be selected.

Here, the core pattern 6 is formed on the rear surface of the semiconductor substrate 1 using the inkjet method to increase a thickness of the core pattern 6, which is more effective to increase a thickness of the mask pattern 7 than a method that forms the mask pattern 7 using a photolithography method. Therefore, even when a thickness of the semiconductor substrate 1 is large, the through hole 9 may be formed in the semiconductor substrate 1 using the mask pattern 7 as a mask.

Further, in the above-described embodiment, even though it has been described that the core pattern 6 for forming the mask pattern 7 is formed using the inkjet method when the through hole 9 is formed in the semiconductor substrate 1, when a pattern other than the mask pattern is formed on the object, the core pattern for forming the mask pattern may be formed using the inkjet method. For example, when the pad electrode 3 is formed, the core pattern for forming the mask pattern may be formed using the inkjet method. In this case, SOG may be desirably used for the core pattern, and polyimide may be desirably used for the mask.

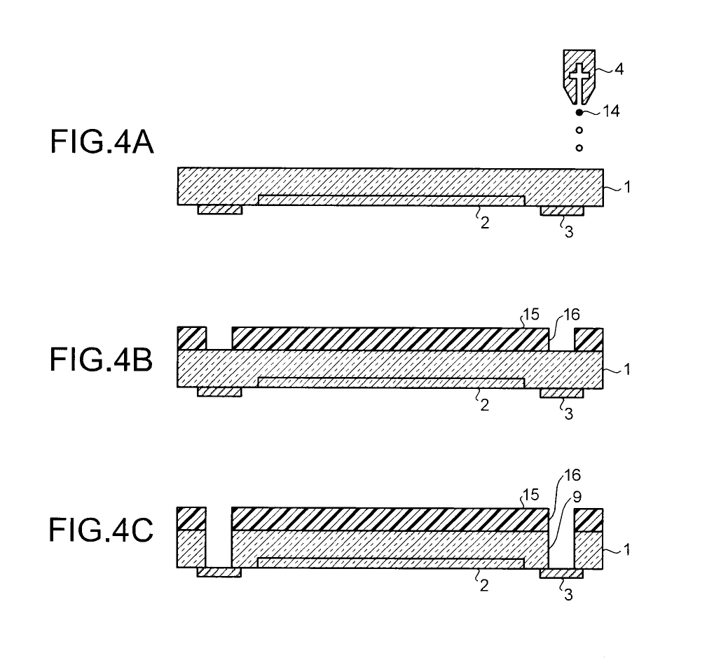

FIGS. 4A to 4C are cross-sectional views illustrating a method of manufacturing a semiconductor device according to a second embodiment. Further, FIGS. 4A to 4C illustrate a portion cut along A-A line of FIG. 1A.

Referring to FIG. 4A, a mask material 14 is ejected on a rear surface of a semiconductor substrate 1 from a nozzle 4 using an inkjet method to form a mask pattern 15 having an opening 16 on the rear surface of the semiconductor substrate 1, as illustrated in FIG. 4B. In this case, the opening 16 is desirably disposed at an inner side of a pad electrode 3. As a material for the mask material 14, for example, an organic film such as a resist or polyimide or an inorganic film such as SOG may be used. A particle size of the mask material 14 may be set to be 50 nm or smaller. A thickness of the mask pattern 15 is desirably 10 μm or larger.

Next, as illustrated in FIG. 4C, the semiconductor substrate 1 is etched from the rear surface using the mask pattern 15 having the opening 16 as a mask to form a through hole 9 in the semiconductor substrate 1. In this case, the through hole 9 may he disposed at the inner side of the pad electrode 3. Further, the rear surface of the pad electrode 3 may be exposed through the through hole 9.

Next, similarly to the processes of FIGS. 3B to 3D, an embedded electrode 12 which is connected to the rear surface of the pad electrode 3 with a seed layer 11 interposed therebetween is embedded in the through hole 9. Therefore, the semiconductor chips P1 to P3 in which the embedded electrodes 12 are embedded are laminated with protruding electrodes 13 therebetween.

Here, the mask pattern 15 is formed on the rear surface of the semiconductor substrate 1 using the inkjet method to increase the thickness of the mask pattern 15 as compared with a method that forms the mask pattern 15 using the photolithography method. Therefore, even when a thickness of the semiconductor substrate 1 is large, the through hole 9 may be formed in the semiconductor substrate 1 using the mask pattern 15 as a mask.

Further, in the above-described embodiments, even though a method that forms the mask pattern 15 for forming the through hole 9 in the semiconductor substrate 1 using the inkjet method has been described, a mask pattern for forming other patterns on the object may be formed using the inkjet method.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern forming method, comprising:
forming a core pattern on an object by ejecting a core material onto the object using an inkjet method;
forming a mask pattern on the object so as to embed the core pattern; and
removing the core pattern which is embedded in the mask pattern.

2. The pattern forming method of claim 1, wherein the mask pattern is formed so as to cover the entire core pattern.

3. The pattern forming method of claim 2, further comprising thinning the mask pattern so as to expose a top surface of the core pattern.

4. The pattern forming method of claim 1, wherein the object is a semiconductor substrate.

5. The pattern forming method of claim 4, wherein a material of the core material is an organic film.

6. The pattern forming method of claim 5, wherein a material of the mask pattern is an SOG.

7. The pattern forming method of claim 4, wherein a pad electrode is formed on the semiconductor substrate, and the core pattern is formed on a rear surface of the semiconductor substrate so as to be overlaid with an inner side of the pad electrode.

8. The pattern forming method of claim 1, wherein a thickness of the core pattern is 10 μm or larger.

9. The pattern forming method of claim 1, wherein a particle size of the core material to be ejected using the inkjet method is 50 nm or smaller.

10. A method of manufacturing a semiconductor device, comprising:
forming a core pattern on an object by ejecting a core material onto the object using an inkjet method;
forming a mask pattern on the object so as to embed the core pattern;
removing the core pattern which is embedded in the mask pattern; and
forming a through hole in the object by etching the object using the mask pattern, from which the core pattern is removed, as a mask.

11. The method of manufacturing a semiconductor device of claim 10, wherein the mask pattern is formed so as to cover the entire core pattern.

12. The method of manufacturing a semiconductor device of claim 11, further comprising thinning the mask pattern so as to expose a top surface of the core pattern.

13. The method of manufacturing a semiconductor device of claim 10, wherein the object is a semiconductor substrate.

14. The method of manufacturing a semiconductor device of claim 13, wherein a material of the core material is an organic film.

15. The method of manufacturing a semiconductor device of claim 14, wherein a material of the mask pattern is an SOG.

16. The method of manufacturing a semiconductor device of claim 13, wherein a pad electrode is formed on the semiconductor substrate, and the core pattern is formed on a rear surface of the semiconductor substrate so as to be overlaid with an inner side of the pad electrode.

17. The method of manufacturing a semiconductor device of claim 16, further comprising:
forming an insulating film on a side wall of the through hole; and
embedding an embedded electrode in the through hole through the insulating film.

18. The method of manufacturing a semiconductor device of claim 17, further comprising:
laminating the semiconductor substrates where the embedded electrode is embedded in the through hole.

19. A method of manufacturing a semiconductor device, comprising:
forming a mask pattern on an object by ejecting a mask material onto the object using an inkjet method; and
forming a through hole in the object by etching the object using the mask pattern as a mask.

20. The method of manufacturing a semiconductor device of claim 19, wherein the object is a semiconductor substrate where a pad electrode is formed on a top surface, the mask pattern is formed on a rear surface of the semiconductor substrate, and an opening is provided on the mask pattern so as to be overlaid with an inner side of the pad electrode.
